(19) United States
(12) Patent Application Publication
(10) Pub. No.: US 2025/0241031 A1
(43) Pub. Date: Jul. 24, 2025

(54) OXIDE SEMICONDUCTOR TRANSISTOR, MANUFACTURING METHOD THEREOF, AND SEMICONDUCTOR DEVICE INCLUDING THE OXIDE SEMICONDUCTOR TRANSISTOR

(71) Applicants: SK hynix Inc., Icheon-si (KR); KOREA UNIVERSITY RESEARCH AND BUSINESS FOUNDATION, Seoul (KR)

(72) Inventors: Hyun-yong YU, Seoul (KR); Jongyoun PARK, Seoul (KR); Sungjoo SONG, Seoul (KR); Jong-hyun KIM, Seoul (KR)

(21) Appl. No.: 19/025,453

(22) Filed: Jan. 16, 2025

(30) Foreign Application Priority Data
Jan. 18, 2024 (KR) 10-2024-0008105

(51) Int. Cl. H10D 62/60; H10D 30/01; H10D 30/67; H10D 62/80

(52) U.S. Cl. CPC H10D 62/60; H10D 30/031; H10D 30/6755; H10D 62/875

(57) ABSTRACT

An oxide semiconductor transistor, a method for manufacturing the same, and a semiconductor device including the oxide semiconductor transistor are disclosed. The disclosed oxide semiconductor transistor may include a gate electrode, a p-type oxide semiconductor channel layer disposed opposite the gate electrode, a gate insulating layer between the gate electrode and the oxide semiconductor channel layer, a source electrode and a drain electrode electrically connected to a first region and a second region of the oxide semiconductor channel layer, respectively, and an intermediate layer disposed between the oxide semiconductor channel layer and the source electrode, as well as between the oxide semiconductor channel layer and the drain electrode, the intermediate layer having an oxygen areal density (OAD) higher than an OAD of the oxide semiconductor channel layer.

### CROSS-REFERENCES TO RELATED APPLICATION

The present application claims, under 35 U.S.C. § 119(a), the benefit of Korean Patent Application No. 10-2024-0008105, filed on Jan. 18, 2024 which is hereby incorporated by reference in its entirety.

### BACKGROUND

### 1. Field

Embodiments of the present disclosure relate to an electronic device, a method of manufacturing the same, and a device comprising the electronic device, and more particularly to a transistor, a method for manufacturing the same, and a semiconductor device comprising the transistor.

### 2. Description of the Related Art

In recent years, monolithic three-dimensional (M3D) integrated/stacked structures have gained attention for highly integrated circuits in semiconductors. Unlike conventional two-dimensional structures, which achieve higher integration through miniaturization of the unit device area, three-dimensional structures have a split bottom/top layer, enabling smaller area complementary metal oxide semiconductor (CMOS) logic circuits with the same size device.

In M3D integrated structures, it is important to reduce the process temperature of the top layer to minimize degradation of the bottom layer, and oxide semiconductor (OS) materials that can be processed at low temperatures are gaining traction as top layer transistor channel materials to replace silicon (Si), which requires high-temperature processing.

The research and development of indium gallium zinc oxide (IGZO), that can be used as an n-type oxide semiconductor channel material, has progressed significantly to the point where it has been commercialized as a thin-film transistor backplane on the latest active-matrix flat panel displays using its low off-current (<3×10⁻¹⁹ A/μm) characteristics due to its wide bandgap.

P-type oxide semiconductor channel materials include, for example, stannous oxide (SnO) (i.e., tin oxide). SnO has been attracting attention as an M3D top layer transistor channel material because its valence band maximum is composed of a highly delocalized isotropic Sn 5s orbital, resulting in high hole mobility among oxide semiconductor channel materials of the same type, and its process temperature is quite low (<300° C.).

However, p-type oxide semiconductor channel materials have high off-current due to narrow bandgap and low hole mobility due to localizing oxygen 2p orbitals compared to n-type oxide semiconductor channel materials, so research on channel characteristic improvement is needed for CMOS logic circuit implementation. In addition, unlike Si-based semiconductor channel materials, oxide semiconductors are difficult to dope in the source/drain region using conventional doping processes (e.g., ion implantation, diffusion, etc.), so research on contact resistance reduction and on-current enhancement technologies is needed. On the other hand, in the case of approaches to improve contact characteristics such as H₂ plasma treatment, there is a problem that characteristic deterioration occurs due to plasma damage.

### SUMMARY

The present disclosure aims to provide an oxide semiconductor transistor that reduces contact resistance to a p-type oxide semiconductor channel layer while enhancing the on-current.

In addition, a technical objective of the present invention is to provide an oxide semiconductor transistor capable of achieving an excellent doping effect for a p-type oxide semiconductor channel layer.

In addition, the present invention is to provide a manufacturing method for an oxide semiconductor transistor that enables a doping effect on a p-type oxide semiconductor channel layer in a simple manner, without requiring thermal treatment and plasma treatment.

Another objective of the present invention is to provide a semiconductor device comprising the oxide semiconductor transistor.

The objectives of the present disclosure are not limited to those mentioned above. Additional objectives will be apparent to those skilled in the art from the following description.

According to one embodiment of the present invention, there is provided an oxide semiconductor transistor comprising: a gate electrode; a p-type oxide semiconductor channel layer disposed opposite the gate electrode; a gate insulating layer between the gate electrode and the oxide semiconductor channel layer; a source electrode and a drain electrode electrically connected to a first region and a second region of the oxide semiconductor channel layer, respectively; and an intermediate layer disposed between the oxide semiconductor channel layer and the source electrode, as well as between the oxide semiconductor channel layer and the drain electrode, the intermediate layer having an oxygen areal density (OAD) higher than an OAD of the oxide semiconductor channel layer, wherein a concentration of oxygen vacancies in a region of the oxide semiconductor channel layer that is in contact with the intermediate layer is lower than a concentration of oxygen vacancies in a region of the oxide semiconductor channel layer that is not in contact with the intermediate layer.

The OAD of the intermediate layer may be at least 1.15 times greater than the OAD of the oxide semiconductor channel layer.

The p-type oxide semiconductor channel layer may include at least one of SnO, ZnRh₂O₄, CuAlO₂, CuO, Cu₂O, NiO₂, Cr₂O₃ and Mn₃O₄.

The intermediate layer may include a dielectric layer.

The intermediate layer may include at least one of ZnO, aluminum-doped zinc oxide (AZO), SiO₂, Y₂O₃, ZrO₂, and TiO₂.

The intermediate layer may have a thickness of less than about 10 nm.

The source electrode and the drain electrode may include a metal or a metallic material.

The oxide semiconductor transistor may have a bottom-gate structure.

According to another embodiment of the present disclosure, there is provided a semiconductor device comprising the aforementioned oxide semiconductor transistor.

The semiconductor device may include, for example, a monolithic three-dimensional (M3D) semiconductor device, and the oxide semiconductor transistor may be implemented to an upper layer region of the M3D semiconductor device.

According to another embodiment of the present invention, there is provided a method for preparing a gate electrode; forming a gate insulating layer on the gate electrode; forming a p-type oxide semiconductor channel layer on the gate insulating layer, such that the p-type oxide semiconductor channel layer faces the gate electrode through the gate insulating layer; and forming an intermediate layer in contact with each of a first region and a second region of the oxide semiconductor channel layer, and forming a source electrode and a drain electrode disposed on the intermediate layer and electrically connected to each of the first region and the second region, respectively. A method of manufacturing an oxide semiconductor transistor is provided, wherein the intermediate layer has an oxygen areal density (OAD) higher than an oxygen vacancy density (OAD) of the oxide semiconductor channel layer, and wherein a concentration of oxygen vacancies in a region of the oxide semiconductor channel layer that is in contact with the intermediate layer is lower than a concentration of oxygen vacancies in a region of the oxide semiconductor channel layer that is not in contact with the intermediate layer.

The OAD of the intermediate layer may be at least 1.15 times greater than the OAD of the oxide semiconductor channel layer.

The p-type oxide semiconductor channel layer may include at least one of SnO, ZnRh₂O₄, CuAlO₂, CuO, Cu₂O, NiO₂, Cr₂O₃ and Mn₃O₄.

The intermediate layer may include a dielectric layer.

The intermediate layer may include at least one of ZnO, aluminum-doped zinc oxide (AZO), SiO₂, Y₂O₃, ZrO₂, and TiO₂.

The intermediate layer may have a thickness of less than about 10 nm.

The step of forming the intermediate layer and the source electrode and drain electrode comprises forming a mask pattern with an opening that exposes the first and second end regions on the gate insulating layer and the oxide semiconductor channel layer; sequentially depositing an intermediate material layer for the intermediate layer and a source/drain electrode material layer for the source/drain electrodes on the first and second end regions exposed by the mask pattern; and removing the mask pattern and portions of the intermediate material layer and the source/drain electrode material layer formed on the mask pattern.

The method of forming the intermediate layer and the source and drain electrodes does not include heat treatment and plasma treatment processes.

According to embodiments of the present disclosure, an oxide semiconductor transistor capable of reducing contact resistance and enhancing the on-current of a p-type oxide semiconductor channel layer can be achieved. In addition, according to embodiments of the present disclosure, an oxide semiconductor transistor capable of securing an excellent doping effect on the p-type oxide semiconductor channel layer can also be achieved.

Furthermore, embodiments of the present disclosure provide a manufacturing method for an oxide semiconductor transistor that enables a doping effect on a p-type oxide semiconductor channel layer in a simple manner, without requiring thermal treatment and plasma treatment.

By incorporating an oxide semiconductor transistor as described in the present disclosure, a semiconductor device having excellent performance can be easily manufactured. As a non-limiting example, the semiconductor device may include a monolithic three-dimensional (M3D) semiconductor device, in which the oxide semiconductor transistor can be implemented in a top layer region of the M3D semiconductor device.

However, the process effects described herein are not exhaustive and may be further extended within the scope and spirit of the present disclosure.

### BRIEF DESCRIPTION OF THE DRAWINGS

FIG. 1 illustrates a cross-sectional view of an oxide semiconductor transistor according to an embodiment of the present disclosure.

FIG. 2 illustrates the principle of contact resistance reduction achieved by MIS structures, as applied to an oxide semiconductor transistor according to an embodiment of the present disclosure.

FIGS. 3A to 3D illustrate graphs showing results of an X-ray photoelectron spectroscopy (XPS) analysis of the composition in a channel layer in an MS structure applicable to an oxide semiconductor transistor according to a comparative example and the composition in a channel layer in an MIS structure applicable to an oxide semiconductor transistor according to an embodiment of the present disclosure.

FIG. 4 is a graph showing the variation of gate voltage-drain current characteristics with intermediate layer thickness of an oxide semiconductor transistor according to an embodiment of the present disclosure.

FIG. 5 is a graph showing the variation of on-current with intermediate layer thickness of an oxide semiconductor transistor according to an embodiment of the present disclosure.

FIGS. 6A through 6F are cross-sectional views illustrating a method for fabricating an oxide semiconductor transistor according to an embodiment of the present disclosure.

FIG. 7 schematically illustrates a semiconductor device with an oxide semiconductor transistor according to an embodiment of the present disclosure.

### DETAILED DESCRIPTION

Hereinafter, the embodiments of the present disclosure will be described in detail with reference to the accompanying drawings.

The embodiments of the present disclosure to be described below are provided to explain the invention more clearly to those having common knowledge in the related art, and the scope of the invention is not limited by the following embodiments. The following embodiments may be modified in many different forms.

The terminology used herein is used to describe specific embodiments, and is not used to limit the invention. As used herein, terms in the singular form may include the plural form unless the context clearly dictates otherwise. Also, as used herein, the terms “comprise” and/or “comprising” indicate presence of the stated shape, step, number, action, member, element and/or group thereof; and does not exclude presence or addition of one or more other shapes, steps, numbers, actions, members, elements, and/or groups thereof. In addition, the term “connection” as used herein means not only a concept that certain members are directly connected, but also a concept that other members are further interposed between the members to be indirectly connected.

In addition, in the present specification, when a member is the to be located “on” another member, this includes not only a case in which a member is in contact with another member but also a case in which another member is present between the two members. As used herein, the term “and/or” includes any one and any combination of one or more of those listed items. In addition, as used herein, terms such as “about”, “substantially”, etc. are used as a range of the numerical value or degree, in consideration of inherent manufacturing and material tolerances, or as a meaning close to the range. Furthermore, accurate or absolute numbers provided to aid the understanding of the present application are used to prevent an infringer from using the disclosed present invention unfairly.

The embodiments of the present disclosure will be described in detail with reference to the accompanying drawings. The sizes or thicknesses of the areas or parts shown in the accompanying drawings may be somewhat exaggerated for clarity and ease of description. Throughout the detailed description, identical reference numerals designate identical components.

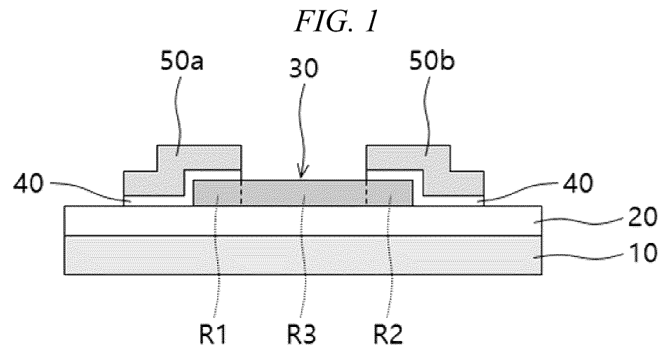

FIG. 1 illustrates a cross-sectional view of an oxide semiconductor transistor according to an embodiment of the present disclosure.

Referring to FIG. 1, the oxide semiconductor transistor may include a gate electrode 10, a p-type oxide semiconductor channel layer 30 disposed over the gate electrode 10, and a gate insulating layer 20 disposed between the gate electrode 10 and the oxide semiconductor channel layer 30 in a stacking direction of the layers 10, 20, and 30.

The gate electrode 10 may be disposed beneath the oxide semiconductor channel layer 30. The gate electrode 10 may include a doped semiconductor, or may include a metal or metallic material. The doped semiconductor may include at least one of Si, Ge, or SiGe. As a non-limiting example, the gate electrode 10 may be formed of Si doped with impurities. However, in some cases, the gate electrode 10 may be formed of a metal or metallic material. The thickness of the gate electrode 10 shown in FIG. 1 is merely exemplary and may vary. For example, the gate electrode 10 may be formed to have the same or a similar thickness as the oxide semiconductor channel layer 30.

Any insulating material commonly used for a gate insulating layer of a typical transistor may be employed for the gate insulating layer 20. The gate insulating layer 20 may include at least one of silicon oxide, silicon nitride, or a high-k material. Here, the high-k material refers to a material having a higher dielectric constant than the silicon nitride. The p-type oxide semiconductor channel layer 30 may be disposed on the gate insulating layer 20.

The oxide semiconductor transistor may further include a source electrode 50a and a drain electrode 50b that are electrically connected to a first region (or first surface region) and a second region (or second surface region) of the oxide semiconductor channel layer 30, respectively. For example, the source electrode 50a may be electrically connected to a first end of the oxide semiconductor channel layer 30, and the drain electrode 50b may be electrically connected to a second end of the oxide semiconductor channel layer 30. The source electrode 50a may be disposed on the first end of the oxide semiconductor channel layer 30 and extend onto a portion of the gate insulating layer 20 adjacent to the first end. Similarly, the drain electrode 50b may be disposed on the second end of the oxide semiconductor channel layer 30 and extend onto a portion of the gate insulating layer 20 adjacent to the second end. The source electrode 50a may be disposed on the first end of the oxide semiconductor channel layer 30 and a first side of the oxide semiconductor channel layer 30 adjacent to the first end. The drain electrode 50b may be disposed on the second end of the oxide semiconductor channel layer 30 and a second side of the oxide semiconductor channel layer 30 adjacent to the second end.

The source electrode 50a and the drain electrode 50b may include a metal or metallic material. As a non-limiting example, the source electrode 50a and the drain electrode 50b may include one or more metals such as Pt, Au, Ti, Mo, W, Bi, Ag, or a similar material, or a combination thereof.

The oxide semiconductor transistor may further include an intermediate layer 40 disposed between the oxide semiconductor channel layer 30 and the source electrode 50a, as well as between the oxide semiconductor channel layer 30 and the drain electrode 50b. The intermediate layer 40 may also be referred to as an insertion layer.

The intermediate layer 40 on the source electrode 50a side may be disposed on the first end of the oxide semiconductor channel layer 30 and extend onto the portion of the gate insulating layer 20 adjacent to the first end. Similarly, the intermediate layer 40 on the drain electrode 50b side may be disposed on the second end of the oxide semiconductor channel layer 30 and extend onto the portion of the gate insulating layer 20 adjacent to the second end. The intermediate layer 40 on the source electrode 50a side may be disposed on the first end of the oxide semiconductor channel layer 30 and on the first side of the oxide semiconductor channel layer 30 adjacent to the first end. The intermediate layer 40 on the drain electrode 50b side may be disposed on the second end of the oxide semiconductor channel layer 30 and on the second side of the oxide semiconductor channel layer 30 adjacent to the second end. When viewed from above, the source electrode 50a and the intermediate layer 40 beneath it may have substantially the same shape. Also, when viewed from above, the drain electrode 50b and the intermediate layer 40 beneath it may have substantially the same shape.

The intermediate layer 40 may have an oxygen area density (OAD) higher than that of the oxide semiconductor channel layer 30. Here, the OAD may correspond to an intrinsic characteristic of the material in a state where the oxide semiconductor channel layer 30 and the intermediate layer 40 are not in contact with each other. The OAD of the intermediate layer 40 in a state (condition) in which it is not in contact with the oxide semiconductor channel layer 30 may be higher than the OAD of the oxide semiconductor channel layer 30 in a state (condition) in which it is not in contact with the intermediate layer 40. In other words, as an intrinsic feature of the material, the OAD of the intermediate layer 40 may be higher than the OAD of the oxide semiconductor channel layer 30.

The concentration of oxygen vacancies in regions of the oxide semiconductor channel layer 30 that are in contact with the intermediate layer 40 may be lower than the concentration of oxygen vacancies in regions of the oxide semiconductor channel layer 30 that are not in contact with the intermediate layer 40. For example, the concentration of oxygen vacancies in the regions labeled R1 and R2 in FIG. 1 may be lower than the concentration of oxygen vacancies in the region labeled R3. The intermediate layer 40 having a relatively high OAD may supply oxygen to the regions of the oxide semiconductor channel layer 30 that abut it, thereby reducing the oxygen vacancy concentration in these regions of the oxide semiconductor channel layer 30. Thus, the oxygen vacancy concentration in the region of the oxide semiconductor channel layer 30 that is in contact with the intermediate layer 40 may be lower than the oxygen vacancy concentration in the region of the oxide semiconductor channel layer 30 that is not in contact with the intermediate layer 40. The intermediate layer 40 may be referred to as an “oxygen providing layer” (OPL). However, the extent of the regions R1, R2, and R3 shown in FIG. 1 is exemplary only and may vary.

Since the oxygen vacancies in the p-type oxide semiconductor channel layer 30 act as hole killers and hole traps, a doping effect may occur in the region of the oxide semiconductor channel layer 30 where the oxygen vacancy concentration is lowered by the intermediate layer 40. That is, a doping effect may occur in a first portion (or source region) of the oxide semiconductor channel layer 30 electrically connected to the source electrode 50a and a second portion (or drain region) of the oxide semiconductor channel layer 30 electrically connected to the drain electrode 50b. Accordingly, the contact resistance between the oxide semiconductor channel layer 30 and the source electrode 50a, as well as between the oxide semiconductor channel layer 30 and the drain electrode 50b, may be reduced, thereby improving the on-current of the oxide semiconductor transistor.

Furthermore, since the dipole at the junction of the oxide semiconductor channel layer 30 and the intermediate layer 40 may form with a negative charge directed toward the oxide semiconductor channel layer 30 and a positive charge directed toward the intermediate layer 40, the valence band of the oxide semiconductor channel layer 30 may bend upward. This upward bending may further lower the effective Schottky barrier height (SBH), thereby reducing the contact resistance between the oxide semiconductor channel layer 30 and both the source electrode 50a and the drain electrode 50b. Consequently, the on-current of the oxide semiconductor transistor may be further improved.

In one embodiment, the OAD of the intermediate layer 40 may be at least about 1.15 times that of the oxide semiconductor channel layer 30, and in some cases, at least about 1.2 times. When the OAD of the intermediate layer 40 is at least about 1.15 times, or at least about 1.2 times, that of the oxide semiconductor channel layer 30, oxygenation and doping effects by the intermediate layer 40 may occur more effectively. On the other hand, the OAD of the intermediate layer 40 may be limited to a value of about 100 times or less that of the oxide semiconductor channel layer 30.

According to an embodiment, the p-type oxide semiconductor channel layer 30 may include at least one of, for example, SnO, ZnRh₂O₄, CuAlO₂, CuO, Cu₂O, NiO₂, Cr₂O₃, or Mn₃O₄. The p-type oxide semiconductor channel layer 30 may be formed of at least one material selected from SnO, ZnRh₂O₄, CuAlO₂, CuO, Cu₂O, NiO₂, Cr₂O₃, and Mn₃O₄. Among these, SnO offers various advantages, as its valence band maximum is composed of a highly delocalized isotropic Sn 5s orbital, which enables high hole mobility and allows for a considerably low process temperature (<300° C.). However, the material of the oxide semiconductor channel layer 30 is not limited to these examples and may be selected based on specific application requirements.

According to one embodiment, the intermediate layer 40 may be a dielectric layer. The intermediate layer 40 may be an insulative dielectric layer. In addition, the intermediate layer 40 may include an oxide, or may be an oxide layer. The intermediate layer 40 may have a thickness of, for example, less than about 10 nm. As a non-limiting example, the intermediate layer 40 may have a thickness of about 5 nm or less. The intermediate layer 40 may have a small thickness, allowing electrical conduction through tunneling. The intermediate layer 40 may not inhibit electrical conduction.

According to an embodiment, the intermediate layer 40 may include at least one of, for example, ZnO, aluminum-doped zinc oxide (AZO), SiO₂, Y₂O₃, ZrO₂, or TiO₂. The intermediate layer 40 may be formed of at least one material selected from ZnO, AZO, SiO₂, Y₂O₃, ZrO₂, and TiO₂. However, the material of the intermediate layer 40 is not limited to these examples and may be selected based on specific application requirements.

According to one embodiment, the intermediate layer 40 may be formed without thermal treatment and plasma treatment. Thus, the intermediate layer 40 and the oxide semiconductor channel layer 30 may be formed without heat damage or plasma damage. In addition, the manufacturing process of the oxide semiconductor transistor may be simplified. Without heat treatment and plasma treatment, the effect of reducing the contact resistance and increasing the on-current may be achieved by a process of further depositing the intermediate layer 40. The greatly simplified process enables the manufacture of oxide semiconductor transistors with high performance, which may be advantageous for mass production and productivity improvement.

The oxide semiconductor transistor according to an embodiment of the present disclosure may be a thin-film transistor (TFT). For example, the oxide semiconductor transistor may be an oxide TFT. The oxide semiconductor transistor may be a p-type oxide semiconductor transistor. The oxide semiconductor transistor may have a bottom-gate structure in which the gate electrode 10 is disposed at the bottom of the channel layer 30. In this case, the oxide semiconductor transistor may be easily manufactured while preventing or minimizing damage to the channel layer 30. However, an oxide semiconductor transistor according to an embodiment is not limited to the bottom-gate structure. In some cases, the oxide semiconductor transistor may have a top-gate structure. In the top-gate structure, the gate electrode 10 is disposed at the top of the channel layer 30.

An oxide semiconductor transistor according to embodiments of the present disclosure may have a metal-dielectric-semiconductor structure. In this structure, the metal may represent the source/drain electrodes 50a and 50b, the dielectric may represent the intermediate layer 40, and the semiconductor may represent the oxide semiconductor channel layer 30.

In addition, the oxide semiconductor transistor may have a metal-intermediate layer-semiconductor contact structure. In this structure, the metal may represent source/drain electrodes 50a and 50b, the intermediate layer may represent the intermediate layer 40 that serves as an oxygen providing layer (OPL), and the semiconductor may represent the oxide semiconductor channel layer 30. The metal-intermediate layer-semiconductor contact structure may be referred to as a MIS contact structure or MIS structure. Utilizing the above MIS contact structure can reduce the contact resistance in the source/drain region and increase the on-current of the transistor.

In a conventional oxide semiconductor transistor, the source/drain contact features a metal-semiconductor structure, leading to Fermi level pinning caused by Dit (interface trap density) and MIGS (metal-induced gap states), resulting in a high SBH (Schottky barrier height). However, the MIS contact structure in the embodiment of the present disclosure may mitigate Dit and MIGS, enabling Fermi level unpinning and a relatively low SBH.

In embodiments of the present disclosure, the intermediate layer 40 may have an OAD higher than that of the oxide semiconductor channel layer 30. OAD may refer to the volume fraction of oxygen in an oxide material. Oxygen in the material tends to migrate from layers with higher OAD to layers with lower OAD, and oxygen vacancies may exhibit the opposite tendency. For example, the OAD of SnO, which may be used for the oxide semiconductor channel layer 30, may be 0.132 cm⁻², and the OAD of ZnO, which may be used for the intermediate layer 40, may be 0.168 cm⁻². This difference suggests that oxygen vacancies tend to migrate from SnO to ZnO.

The MIS contact structure with an oxygen providing layer (OPL) may reduce the oxygen vacancy concentration in the oxide semiconductor channel layer 30, which acts as a hole killer and a hole trap. This reduction can result in a doping effect on the source/drain region of the oxide semiconductor channel layer 30 in the oxide semiconductor transistor.

Doping via MIS contact structures with an oxygen providing layer (OPL) offers the advantage of doping the source/drain region without the need for plasma treatment, thereby avoiding plasma-induced damage to the channel.

In addition, the dipole at the junction of the oxide semiconductor channel layer 30 and the intermediate layer 40 may form with the negative charge directed toward the oxide semiconductor channel layer 30 and the positive charge directed toward the intermediate layer 40. This configuration can cause upward bending of the valence band in the oxide semiconductor channel layer 30, further lowering the effective Schottky barrier height (SBH).

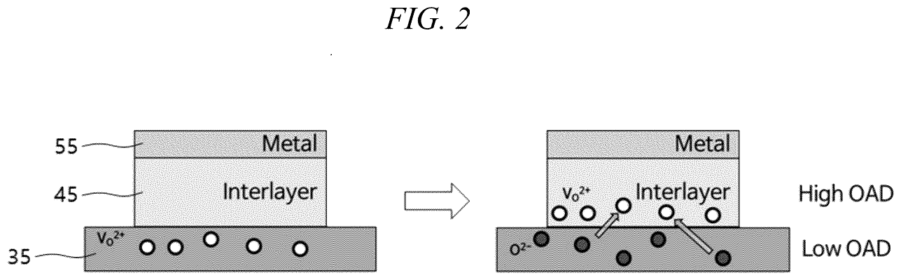

FIG. 2 illustrates the principle of contact resistance reduction achieved by MIS structures, applied to an oxide semiconductor transistor according to an embodiment of the present disclosure.

Referring to FIG. 2, a MIS structure may be applied to an oxide semiconductor transistor according to an embodiment of the present disclosure. The MIS structure may include a p-type oxide semiconductor channel layer 35, a source/drain electrode 55, and an intermediate layer 45 disposed therebetween. For illustrative convenience, the intermediate layer 45 is depicted as thick in FIG. 2. The oxygen areal density (OAD) of the intermediate layer 45 may be higher than the OAD of the oxide semiconductor channel layer 35. Oxygen (O²⁻) may be supplied from the intermediate layer 45 to regions of the oxide semiconductor channel layer 35 in contact with it, while oxygen vacancies (Vo²⁺) may migrate from the regions of the oxide semiconductor channel layer 35 to the intermediate layer 45. Thus, the oxygen vacancy concentration in the regions of the oxide semiconductor channel layer 35 in contact with the intermediate layer 45 may be lowered.

Since oxygen vacancies in the p-type oxide semiconductor channel layer 35 act as hole killers and hole traps, a doping effect may occur in the regions of the oxide semiconductor channel layer 35 where the oxygen vacancy concentration is lowered by the intermediate layer 45. This may be a doping effect caused by diffusion of oxygen ions. Thus, the contact resistance between the oxide semiconductor channel layer 35 and the source/drain electrode 55 may be lowered, and the on-current of the oxide semiconductor transistor may be improved. In addition, the doping effect on the oxide may be generated without the need for plasma treatment or heat treatment, thereby preventing damage to the contact portion that could result from such plasma treatment or heat treatment.

In addition, the MIS structure may mitigate the Dit and MIGS phenomena, and a relatively low Schottky barrier height (SBH) may be formed through Fermi level unpinning. Furthermore, the dipole at the junction of the oxide semiconductor channel layer 35 and the intermediate layer 45 may form with the negative charge directed toward the oxide semiconductor channel layer 35 and the positive charge directed toward the intermediate layer 45. This configuration can cause upward bending of the valence band in the oxide semiconductor channel layer 35, further reducing the effective SBH.

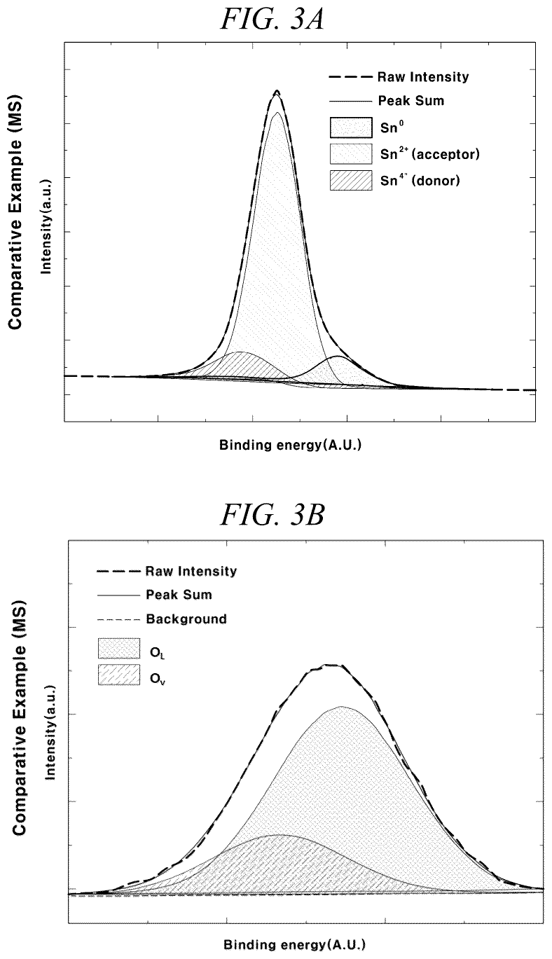

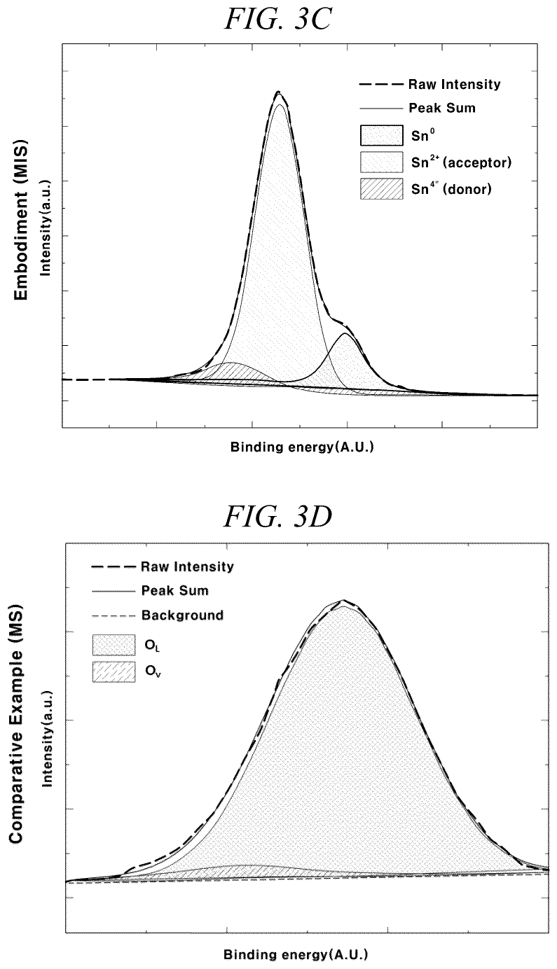

FIGS. 3A to 3D are graphs showing results of an X-ray photoelectron spectroscopy (XPS) analysis of the composition in a channel layer of an MS structure applicable to an oxide semiconductor transistor according to a comparative example and the composition in a channel layer of an MIS structure applicable to an oxide semiconductor transistor according to an embodiment of the present disclosure. Here, the MIS structure refers to a metal-intermediate layer-semiconductor contact structure, and the MS structure refers to a metal-semiconductor contact structure without an intermediate layer. Here, the semiconductor (channel layer) is a SnO layer and the intermediate layer is a ZnO layer. In FIG. 3, O_{L} represents oxygen, and O_{V} represents an oxygen vacancy.

Referring to FIGS. 3A to 3D, the Sn 3d_{5/2} orbital according to an embodiment of the present disclosure shows that the oxygen vacancy, which acts as a hole killer in the SnO channel, has been reduced, and therefore Sn²⁺ and Sn⁰ phases, which can act as hole carriers in the MIS structure compared to the MS structure, have been increased by 1% and 3.33%, respectively. In addition, the O 1s orbitals show that the oxygen vacancies in the SnO channel of the oxide semiconductor transistor are reduced by about 17% in the MIS structure compared to the MS structure. Therefore, in the case of the MIS structure, the oxygen vacancy concentration in the region of the semiconductor channel layer bordered by the intermediate layer may be reduced, and as a result, the contact resistance may be reduced, the contact characteristics may be improved, and the on-current of the transistor may be improved.

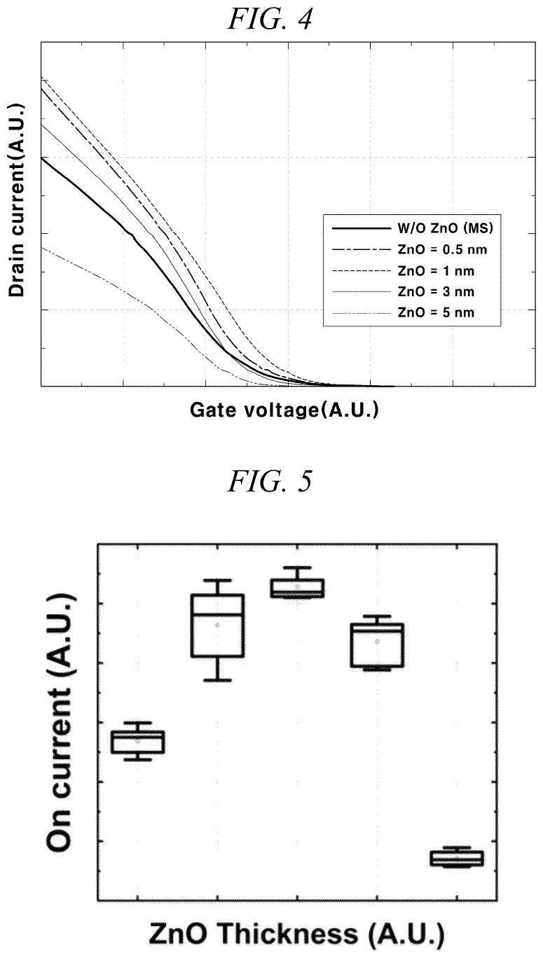

FIG. 4 is a graph (i.e., transfer curve) illustrating the variation of gate voltage-drain current characteristics as a function of intermediate layer thickness of an oxide semiconductor transistor according to an embodiment of the present disclosure. Here, the channel layer is SnO and the intermediate layer is ZnO. The designation “W/O ZnO (MS)” corresponds to an oxide semiconductor transistor according to a comparative example without an intermediate layer.

Referring to FIG. 4, the contact resistance and Schottky barrier height (SBH) exhibit the lowest values when the thickness of the intermediate layer, i.e., the ZnO layer, is about 1 nm. The doping effect by the intermediate layer and the series resistance of the intermediate layer (insulating dielectric layer) may have a trade-off relationship. The doping effect and resistance reduction can be optimized at a specific thickness of the intermediate layer. More specifically, when the thickness of the intermediate layer is 1 nm, the SBH may be about 0.39 eV, and the contact resistance may be about 5e−4Ω·cm², representing reductions of about 0.14 eV and three orders of magnitude, respectively, compared to the conventional MS contact structure.

In the channel layer of the p-type oxide semiconductor, the oxygen vacancy may act as a donor. By applying an oxygen-supplying intermediate layer, the concentration of oxygen vacancies in the region of the channel layer in contact with the intermediate layer may be reduced. This reduction can increase the number of acceptors and result in doping of the source/drain region due to the decrease in donor concentration.

FIG. 5 is a graph showing the variation of the on-current with the thickness of the intermediate layer in an oxide semiconductor transistor according to an embodiment of the present disclosure. Here, the channel layer is a SnO layer, and the intermediate layer is a ZnO layer. The thicknesses of the intermediate layer are 0 nm, 0.5 nm, 1 nm, 3 nm, and 5 nm from left to right. A thickness of 0 nm corresponds to an oxide semiconductor transistor according to a comparative example without an intermediate layer, i.e., an oxide semiconductor transistor having an MS structure.

Referring to FIG. 5, similar to the results in FIG. 4, the highest on-current characteristics are observed for the intermediate layer with a thickness of about 1 nm. This indicates that the source/drain region of the channel layer is doped at a higher concentration with the MIS structure, which includes an oxygen providing layer (OPL), compared to the conventional MS structure, resulting in reduced contact resistance. In addition, as the concentration of oxygen vacancies, which act as hole killers and hole traps, decreases, the field effect mobility in the channel layer peaks at the same intermediate layer thickness. The increase in the on-current of the p-type oxide semiconductor transistor according to the embodiments may be attributed to the decrease in donors and increase in acceptors due to the intermediate layer.

However, the results of FIGS. 4 and 5 are based on the case where the channel layer includes SnO and the intermediate layer includes ZnO. Depending on manufacturing conditions and other factors, the range of suitable intermediate layer thicknesses may vary if the material of the channel layer and/or the intermediate layer is changed.

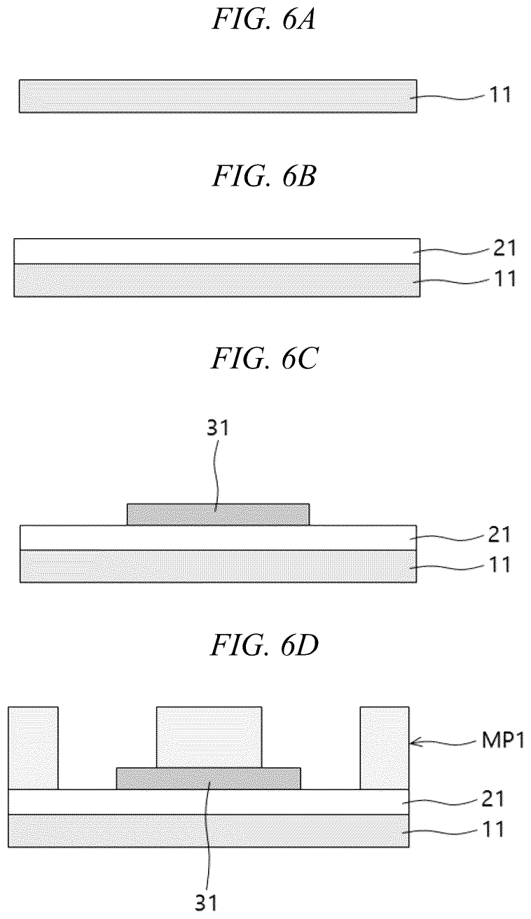

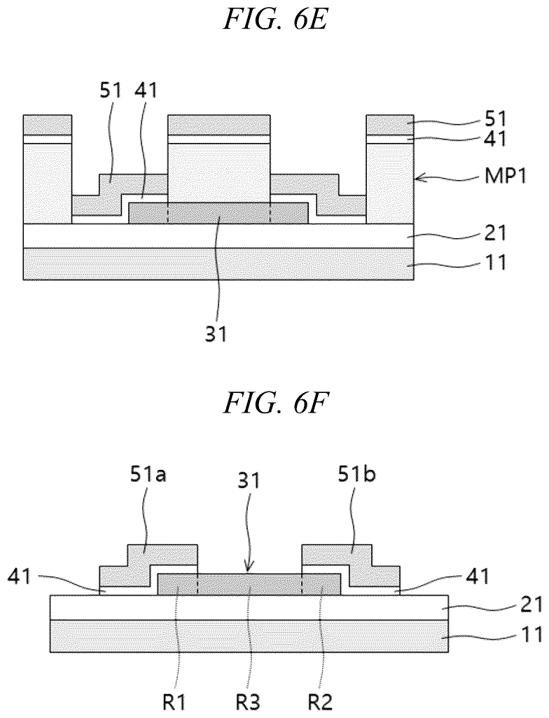

FIGS. 6A through 6F illustrates a method of fabricating an oxide semiconductor transistor according to an embodiment of the present disclosure.

Referring to FIG. 6A, a gate electrode 11 may be provided. The gate electrode 11 may include a doped semiconductor, or may include a metal or metallic material. The doped semiconductor may include at least one of Si, Ge, or SiGe. As a non-limiting example, the gate electrode 11 may be formed of Si doped with impurities. However, in some cases, the gate electrode 11 may be formed of a metal or metallic material. The thickness of the gate electrode 11 shown herein is exemplary only, and the thickness of the gate electrode 11 may vary.

Referring to FIG. 6B, a gate insulating layer 21 may be formed on the gate electrode 11. The material of the gate insulating layer 21 can be any insulating material typically used in a general transistor. The gate insulating layer 21 may include at least one of silicon oxide, silicon nitride, or a high-k material. Here, the high-k material may refer to a material having a higher dielectric constant than the silicon nitride.

Referring to FIG. 6C, a p-type oxide semiconductor channel layer 31 may be formed on the gate insulating layer 21, opposite the gate electrode 11. The oxide semiconductor channel layer 31 may be formed, for example, by a sputtering or atomic layer deposition (ALD) method. As a non-limiting example, the oxide semiconductor channel layer 31 may be formed through a low temperature process, below about 300° C., using sputtering and furnace techniques.

According to one embodiment, the p-type oxide semiconductor channel layer 31 may include at least one of SnO, ZnRh₂O₄, CuAlO₂, CuO, Cu₂O, NiO₂, Cr₂O₃, or Mn₃O₄. The p-type oxide semiconductor channel layer 31 may be formed of at least one material selected from SnO, ZnRh₂O₄, CuAlO₂, CuO, Cu₂O, NiO₂, Cr₂O₃, and Mn₃O₄. In particular, SnO offers several advantages due to its valence band maximum, which is composed of a highly delocalized, isotropic Sn 5s orbital. This results in high hole mobility and a relatively low processing temperature (<300° C.). However, the material of the oxide semiconductor channel layer 31 is not limited to these examples and may vary depending on the applications.

Then, as shown in FIGS. 6D to 6F, an intermediate layer 41 is formed in contact with each of a first region and a second region of the oxide semiconductor channel layer 31, with a source electrode 51a and a drain electrode 51b each disposed on the intermediate layer 41. These electrodes 51a and 51b are electrically connected to the first region and the second region, respectively. More specifically, the method of forming the intermediate layer 41 and the source and drain electrodes 51a and 51b will be described below.

Referring to FIG. 6D, an opening mask pattern MP1 that exposes the first region (or first surface region) and the second region (or second surface region) of the oxide semiconductor channel layer 31 may be formed on the gate insulating layer 21 and the oxide semiconductor channel layer 31. The mask pattern MP1 may include, for example, a photoresist. In forming the mask pattern MP1, an exposure and development process may be applied. The opening pattern MP1 may expose the first region of the oxide semiconductor channel layer 31 while exposing a top surface region of the gate insulating layer 21 adjacent thereto. In addition, the opening pattern MP1 may expose the second region of the oxide semiconductor channel layer 31 while exposing a top surface of the gate insulating layer 21 adjacent thereto.

Referring to FIG. 6E, an intermediate material layer for forming the intermediate layer 41 and a source/drain electrode material layer for forming the source and drain electrodes 51a and 51b may be formed (e.g., deposited) on the first and second regions exposed by the mask pattern MP1 and the aperture pattern, one after the other. The intermediate material layer 41 may be formed (or deposited) at a relatively low thickness, for example, by sputtering or atomic layer deposition (ALD). The source/drain electrode material layer 51 may be deposited, for example, by evaporation. As a non-limiting example, the source/drain electrode material layer 51 may be formed of a metal or metallic material using an e-beam evaporation process. As a non-limiting example, the source/drain electrode material layer 51 may include at least one of various metals including Pt, Au, Ti, Mo, W, Bi, Ag, and the like. Although it is not shown, the intermediate material layer 41 and the source/drain electrode material layer 51 may also be formed on sidewalls of the mask pattern MP1.

Referring to FIG. 6F, the mask pattern MP1 and the intermediate material layer 41 and the source/drain electrode material layer 51 formed on the mask pattern MP1 may be removed. As the mask pattern MP1 is removed, the intermediate material layer 41 and the source/drain electrode material layer 51 formed thereon may be removed together. Such a process may be a lift-off process.

In FIG. 6F, the source/drain electrode material layer 51 remaining on the first region of the oxide semiconductor channel layer 31 forms the source electrode 51a, while the source/drain electrode material layer 51 remaining on the second region of the oxide semiconductor channel layer 31 forms the drain electrode 51b. In addition, the intermediate material layer 41 remaining between the oxide semiconductor channel layer 31 and the source electrode 51a, as well as between the oxide semiconductor channel layer 31 and the drain electrode 51b, is referred to as the intermediate layer 41.

The intermediate layer 41 may have an OAD higher than that of the oxide semiconductor channel layer 31. Here, the OAD may correspond to an intrinsic characteristic of the material in a state where the oxide semiconductor channel layer 31 and the intermediate layer 41 are not in contact with each other. The OAD of the intermediate layer 41 in a state (condition) in which it is not in contact with the oxide semiconductor channel layer 31 may be higher than the OAD of the oxide semiconductor channel layer 31 in a state (condition) in which it is not in contact with the intermediate layer 41. In other words, as an intrinsic feature of the material, the OAD of the intermediate layer 41 may be higher than the OAD of the oxide semiconductor channel layer 31.

The concentration of oxygen vacancies in regions of the oxide semiconductor channel layer 31 that are in contact with the intermediate layer 41 may be lower than the concentration of oxygen vacancies in regions of the oxide semiconductor channel layer 31 that are not in contact with the intermediate layer 41. For example, the concentration of oxygen vacancies in the regions labeled R1 and R2 in FIG. 6F may be lower than the concentration of oxygen vacancies in the region labeled R3. The intermediate layer 41 having a relatively high OAD may supply oxygen to the regions of the oxide semiconductor channel layer 31 that abut it, thereby reducing the oxygen vacancy concentration in these regions of the oxide semiconductor channel layer 31. Thus, the oxygen vacancy concentration in a region of the oxide semiconductor channel layer 31 that is in contact with the intermediate layer 41 may be lower than the oxygen vacancy concentration in a region of the oxide semiconductor channel layer 31 that is not in contact with the intermediate layer 41. The intermediate layer 41 may be referred to as an “oxygen providing layer” (OPL). However, the extent of the regions R1, R2, and R3 shown in FIG. 6F is exemplary only and may vary.

Since the oxygen vacancies in the p-type oxide semiconductor channel layer 31 act as hole killers and hole traps, a doping effect may occur in the region of the oxide semiconductor channel layer 31 where the oxygen vacancy concentration is lowered by the intermediate layer 41. That is, a doping effect may occur in a first portion (or source region) of the oxide semiconductor channel layer 31 electrically connected to the source electrode 51a and a second portion (or drain region) of the oxide semiconductor channel layer 31 electrically connected to the drain electrode 51b. Accordingly, the contact resistance between the oxide semiconductor channel layer 31 and the source electrode 51a, as well as between the oxide semiconductor channel layer 31 and the drain electrode 51b, may be lowered, thereby improving the on-current of the oxide semiconductor transistor.

In addition, since the dipole at the junction of the oxide semiconductor channel layer 31 and the intermediate layer 41 may form with the negative charge directed toward the oxide semiconductor channel layer 31 and the positive charge directed toward the intermediate layer 41, the valence band of the oxide semiconductor channel layer 31 may bend upward. This upward bending may further lower the effective Schottky barrier height (SBH), thereby reducing the contact resistance between the oxide semiconductor channel layer 31 and both the source electrode 51a and the drain electrode 51b. Consequently, the on-current of the oxide semiconductor transistor may be further improved.

In one embodiment, the OAD of the intermediate layer 41 may be at least about 1.15 times that of the oxide semiconductor channel layer 31, and in some cases, at least about 1.2 times. When the OAD of the intermediate layer 41 is at least about 1.15 times, or at least about 1.2 times, that of the oxide semiconductor channel layer 31, oxygenation and doping effects by the intermediate layer 41 may occur more effectively. On the other hand, the OAD of the intermediate layer 41 may be limited to a value of about 100 times or less that of the oxide semiconductor channel layer 31.

According to one embodiment, the intermediate layer 41 may be a dielectric layer. The intermediate layer 41 may be an insulating dielectric layer. In addition, the intermediate layer 41 may include an oxide or may be an oxide layer. The intermediate layer 41 may have a thickness of, for example, less than about 10 nm. As a non-limiting example, the intermediate layer 41 may have a thickness of about 5 nm or less. The intermediate layer 41 may have a small thickness, allowing electrical conduction through tunneling. The intermediate layer 41 may not impede electrical conduction.

According to one embodiment, the intermediate layer 41 may include at least one of, for example, ZnO, AZO, SiO₂, Y₂O₃, ZrO₂, or TiO₂. The intermediate layer 41 may be formed of at least one material selected from ZnO, AZO, SiO₂, Y₂O₃, ZrO₂, and TiO₂. However, the material of the intermediate layer 41 is not limited to these examples and may be selected based on specific application requirements.

According to one embodiment, the intermediate layer 41 and the intermediate material layer 41 may be formed without thermal treatment and plasma treatment. Thus, the intermediate layer 41 and the oxide semiconductor channel layer 31 may be formed without heat damage or plasma damage. In addition, the manufacturing process of the above oxide semiconductor transistor may be simplified. Without heat treatment and plasma treatment, the effect of reducing the contact resistance and increasing the on-current may be achieved by a process of further depositing the intermediate layer 41 only. The greatly simplified process enables the manufacture of oxide semiconductor transistors with high performance, which may be advantageous for mass production and productivity improvement.

The oxide semiconductor transistor according to an embodiment of the present disclosure may be a thin-film transistor (TFT). For example, the oxide semiconductor transistor may be an oxide TFT. The oxide semiconductor transistor may be a p-type oxide semiconductor transistor. The oxide semiconductor transistor may have a bottom-gate structure in which the gate electrode 11 is disposed at the bottom of the channel layer 31. In this case, the oxide semiconductor transistor may be easily manufactured while preventing or minimizing damage to the channel layer 31. However, an oxide semiconductor transistor according to an embodiment is not limited to a bottom-gate structure. In some cases, the oxide semiconductor transistor may be formed in a top-gate structure. Furthermore, the specific fabrication methods of the oxide semiconductor transistors described with reference to FIGS. 6A to 6F are exemplary and may vary.

According to an embodiment of the present disclosure, a semiconductor device including the oxide semiconductor transistor according to the foregoing embodiments may be provided. For example, the semiconductor device may include a monolithic three-dimensional (M3D) semiconductor device, and the oxide semiconductor transistor may be implemented in a top layer region (or top level device layer) of the M3D semiconductor device. The techniques according to embodiments of the present disclosure may be usefully applied to the source/drain contact structure of oxide semiconductor transistors for implementing CMOS logic circuits in next-generation M3D integrated structures. In addition, oxide semiconductor transistors according to embodiments of the present disclosure may be applied to CMOS logic circuits that include oxide semiconductor-based devices, as well as inverter devices (inverter unit cells) including oxide semiconductor-based devices. These oxide semiconductor transistors may also be used in various logic devices, memory devices, display devices, and other applications.

p-type oxide semiconductors generally have inferior performance compared to n-type oxide semiconductor channel materials. For example, p-type oxide semiconductors may exhibit a valence band maximum due to a localized O 2p orbital, resulting in high off-current and high hole effective mass. The techniques presented in embodiments of the present disclosure may provide process flexibility and improve the properties of p-type oxide semiconductor channels in a simple way. These advancements may contribute to the utilization and commercialization of p-type oxide semiconductors in CMOS logic circuits and various other device applications.

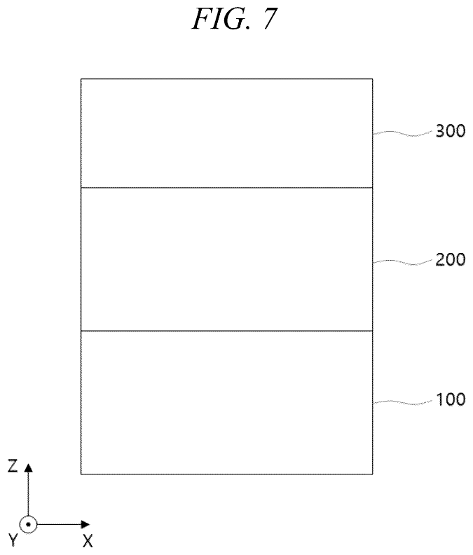

FIG. 7 schematically illustrates an example of a semiconductor device with an oxide semiconductor transistor according to an embodiment of the present disclosure.

Referring to FIG. 7, the semiconductor device may include a monolithic three-dimensional (M3D) semiconductor device. The M3D semiconductor device may include a lower layer region 100 and an upper layer region 200 disposed on the lower layer region 100. The lower layer region 100 may be referred to as a “lower level device layer,” and the upper layer region 200 may be referred to as an “upper level device layer”. In the upper layer region 200, the oxide semiconductor transistor may be applied. The M3D semiconductor device may further include a wiring layer region 300 disposed on the top layer region 200. Also, although not shown, the M3D semiconductor device may further include an intermediate connection disposed between the lower layer region 100 and the upper layer region 200.

However, the applications of the oxide semiconductor transistors according to embodiments of the present disclosure are not limited to M3D semiconductor devices, and the oxide semiconductor transistors may be usefully applied in a variety of device applications.

According to the embodiments of the present disclosure described above, an oxide semiconductor transistor capable of reducing contact resistance and improving the on-current of a p-type oxide semiconductor channel layer can be achieved. In addition, according to embodiments of the present disclosure, an oxide semiconductor transistor capable of securing an excellent doping effect on a p-type oxide semiconductor channel layer can also be achieved.

In addition, according to embodiments of the present disclosure, a manufacturing method of an oxide semiconductor transistor that enables a doping effect on a p-type oxide semiconductor channel layer in a simple manner, without requiring thermal treatment and plasma treatment may be realized. By incorporating an oxide semiconductor transistor as described in the present disclosure, a semiconductor device having excellent performance can be easily manufactured. As a non-limiting example, the semiconductor device may be configured to include an M3D semiconductor device.

This description discloses preferred embodiments of the present invention, and although certain terms are used, they are used in a general sense only to facilitate the description and understanding of the invention and are not intended to limit the scope of the invention. In addition to the embodiments disclosed herein, other modifications based on the technical ideas of the present invention are possible, as will be apparent to those of ordinary skill in the art to which the present invention belongs. One of ordinary skill in the art will recognize that the oxide semiconductor transistors, methods of manufacturing the oxide semiconductor transistors, and semiconductor devices including the oxide semiconductor transistors according to the embodiments described with reference to FIGS. 1 through 7 may be subject to various substitutions, changes, and modifications without departing from the technical ideas of the present invention. As a specific example, in some cases, an intermediate layer material having an oxygen area density (OAD) less than or equal to that of the p-type oxide semiconductor channel layer material, or a material capable of mitigating the Fermi level pinning effect due to the narrow bandgap of the p-type oxide semiconductor channel layer, may also be applicable as an intermediate layer material. In addition, various changes and modifications can be made to the structure and manufacturing method of the oxide semiconductor transistor. The scope of the invention is therefore not to be limited by the embodiments described, but by the technical ideas recited in the patent claims.

What is claimed is:

1. An oxide semiconductor transistor, comprising:
a gate electrode;
a p-type oxide semiconductor channel layer disposed over the gate electrode;
a gate insulating layer between the gate electrode and the oxide semiconductor channel layer;
a source electrode and a drain electrode electrically connected to a first region and a second region of the oxide semiconductor channel layer, respectively; and
an intermediate layer disposed between the oxide semiconductor channel layer and the source electrode, as well as between the oxide semiconductor channel layer and the drain electrode, the intermediate layer having an oxygen areal density (OAD) higher than an OAD of the oxide semiconductor channel layer,
wherein a concentration of oxygen vacancies in a region of the oxide semiconductor channel layer that is in contact with the intermediate layer is lower than a concentration of oxygen vacancies in a region of the oxide semiconductor channel layer that is not in contact with the intermediate layer.

2. The oxide semiconductor transistor of claim 1, wherein the OAD of the intermediate layer is at least 1.15 times greater than the OAD of the oxide semiconductor channel layer.

3. The oxide semiconductor transistor of claim 1, wherein the p-type oxide semiconductor channel layer includes at least one of SnO, ZnRh₂O₄, CuAlO₂, CuO, Cu₂O, NiO₂, Cr₂O₃, or Mn₃O₄.

4. The oxide semiconductor transistor of claim 1, wherein the intermediate layer includes a dielectric layer.

5. The oxide semiconductor transistor of claim 1, wherein the intermediate layer includes at least one of ZnO, aluminum-doped zinc oxide (AZO), SiO₂, Y₂O₃, ZrO₂, or TiO₂.

6. The oxide semiconductor transistor of claim 1, wherein the intermediate layer has a thickness of less than 10 nm.

7. The oxide semiconductor transistor of claim 1, wherein the source electrode and the drain electrode include a metal or metallic material.

8. The oxide semiconductor transistor of claim 1, wherein the oxide semiconductor transistor has a bottom-gate structure.

9. A semiconductor device comprising an oxide semiconductor transistor, wherein the oxide semiconductor transistor comprises:
a gate electrode;
a p-type oxide semiconductor channel layer disposed over the gate electrode;
a gate insulating layer between the gate electrode and the oxide semiconductor channel layer;
a source electrode and a drain electrode electrically connected to a first region and a second region of the oxide semiconductor channel layer, respectively; and
an intermediate layer disposed between the oxide semiconductor channel layer and the source electrode, as well as between the oxide semiconductor channel layer and the drain electrode, the intermediate layer having an oxygen areal density (OAD) higher than an OAD of the oxide semiconductor channel layer,
wherein a concentration of oxygen vacancies in a region of the oxide semiconductor channel layer that is in contact with the intermediate layer is lower than a concentration of oxygen vacancies in a region of the oxide semiconductor channel layer that is not in contact with the intermediate layer.

10. The semiconductor device of claim 9, wherein the semiconductor device includes a monolithic three-dimensional (M3D) semiconductor device, and the oxide semiconductor transistor is implemented in an upper layer region of the M3D semiconductor device.

11. A method for manufacturing an oxide semiconductor transistor, the method comprising:
preparing a gate electrode;
forming a gate insulating layer on the gate electrode;
forming a p-type oxide semiconductor channel layer on the gate insulating layer, such that the p-type oxide semiconductor channel layer faces the gate electrode through the gate insulating layer; and
forming an intermediate layer in contact with each of a first region and a second region of the oxide semiconductor channel layer; and
forming a source electrode and a drain electrode disposed on the intermediate layer and electrically connected to each of the first region and the second region, respectively,
wherein the intermediate layer has an oxygen areal density (OAD) higher than an OAD of the oxide semiconductor channel layer, and
wherein a concentration of oxygen vacancies in a region of the oxide semiconductor channel layer that is in contact with the intermediate layer is lower than a concentration of oxygen vacancies in a region of the oxide semiconductor channel layer that is not in contact with the intermediate layer.

12. The method of claim 11, wherein the OAD of the intermediate layer is at least 1.15 times greater than the OAD of the oxide semiconductor channel layer.

13. The method of claim 11, wherein the p-type oxide semiconductor channel layer includes at least one of SnO, ZnRh₂O₄, CuAlO₂, CuO, Cu₂O, NiO₂, Cr₂O₃, or Mn₃O₄.

14. The method of claim 11, wherein the intermediate layer includes a dielectric layer.

15. The method of claim 11, wherein the intermediate layer includes at least one of ZnO, aluminum-doped zinc oxide (AZO), SiO₂, Y₂O₃, ZrO₂, or TiO₂.

16. The method of claim 11, wherein the intermediate layer has a thickness of less than 10 nm.

17. The method of claim 11, wherein forming the intermediate layer and the source and drain electrodes, comprising:
forming a mask pattern with an opening that exposes the first and second end regions on the gate insulating layer and the oxide semiconductor channel layer;
sequentially depositing an intermediate material layer for the intermediate layer and a source/drain electrode material layer for the source and drain electrodes on the first and second end regions exposed by the mask pattern; and
removing the mask pattern and portions of the intermediate material layer and the source/drain electrode material layer formed on the mask pattern,
wherein the forming of the intermediate layer and the source and drain electrodes does not include heat treatment and plasma treatment processes.
